(19) United States
(12) Patent Application Publication
(10) Pub. No.: US 2016/0276308 A1
(43) Pub. Date: Sep. 22, 2016

(54) THERMALLY ENHANCED PACKAGE-ON-PACKAGE STRUCTURE

(71) Applicant: Samsung Electronics Co., Ltd., Suwon-si (KR)

(72) Inventors: Sunghwan MIN, Sunnyvale, CA (US); YoonHa JUNG, Suwon-si (KR); Jungyong CHOI, San Jose, CA (US); Sung Hoon KIM, Sunnyvale, CA (US)

(21) Appl. No.: 14/806,604

(22) Filed: Jul. 22, 2015

Related U.S. Application Data
(60) Provisional application No. 62/134,540, filed on Mar. 17, 2015.

(51) Int. Cl. H01L 25/065; H01L 23/498; H01L 23/31; H01L 23/367

(52) U.S. Cl. CPC H01L 25/0652; H01L 23/367; H01L 23/49827; H01L 23/3128; H01L 2225/06589; H01L 2225/06548

(57) ABSTRACT

A semiconductor package comprises a bottom package and a top package. The bottom package comprises at least one bottom-package semiconductor device. The top package is on the bottom package and comprises a first side, a second side, a package substrate, a plurality of top-package semiconductor devices, and at least one thermal path. The package substrate is disposed at the first side of the top package. The plurality of top-package semiconductor devices is disposed on the package substrate. The at least one thermal path is disposed between a first top-package semiconductor device and a second top-package semiconductor device, and the thermal path extends from the first side of the top package through the package substrate to the second side of the top package.

### CROSS-REFERENCE TO RELATED APPLICATION

This application claims priority under 35 U.S.C. §120 to U.S. Provisional Patent Application Ser. No. 62/134,540, filed on Mar. 17, 2015, the contents of which are incorporated by reference in their entirety herein.

### BACKGROUND

As performance of electronic products has been improved, heat energies generated from devices used in electronic products have increased. Some electronic products include package-on-package (POP) structures that comprise a bottom package having one or more semiconductor devices and a top package that also has one or more semiconductor devices. The general configuration of a POP structure makes it challenging to remove the heat energy generated by semiconductor devices in a bottom package of a POP structure.

### SUMMARY

Embodiments disclosed herein provide a package-on-package (POP) structure comprising a top package and a bottom package. The top package comprises a multilayer package substrate comprising a first side and a second side; a plurality of top-package semiconductor devices on the first side of the package substrate; a molding material layer formed on and between the plurality of top-package semiconductor devices; and a thermal path disposed between a first top-package semiconductor device and a second top-package semiconductor device in which the thermal path extends from the second side of the multilayer package substrate to a top surface of the molding material layer.

In one exemplary embodiment, the POP structure further comprises a bottom package comprising at least one bottom-package semiconductor device, and the at least one thermal path is disposed over and is thermally coupled to the at least one bottom-package semiconductor device. In one exemplary embodiment, the at least one thermal path is disposed substantially centered over the thermal hot spots of the at one bottom-package semiconductor device.

In one exemplary embodiment, the at least one bottom-package semiconductor device comprises a backside metallization that is thermally coupled to the at least one thermal path.

In one exemplary embodiment, the top package further comprises a thermal interface material (TIM) layer formed on a top surface of the molding material layer; and a heat slug formed on a top surface of the TIM layer.

In one exemplary embodiment, the at least one thermal path comprises at least one via extending through the top package from the second side of the package substrate to the top surface of the molding material layer, the at least one via being filled with a low thermal resistance material.

In one exemplary embodiment, the package substrate comprises at least one via extending through the package substrate and in alignment with the at least one thermal path, the at least one via extending through the package substrate being filled with a low thermal resistance material, and the at least one thermal path comprises extending through the top package from the first side of the package substrate to the top surface of the molding material layer in alignment with the at least one via extending through the package substrate, the at least one heat slug being mounted on top of the multilayer package substrate or one trench being filled with a low thermal resistance material.

Embodiments disclosed herein provide a semiconductor package comprising a bottom package comprising at least one bottom-package semiconductor device; and a top package on the bottom package. The top package comprises a first side, a second side, a package substrate disposed at the first side of the top package, a plurality of top-package semiconductor devices disposed on the package substrate, and at least one thermal path disposed between a first top-package semiconductor device and a second top-package semiconductor device in which the thermal path extends from the first side of the top package through the package substrate to the second side of the top package.

In one exemplary embodiment, the at least one thermal path is disposed over and is thermally coupled to the at least one bottom-package semiconductor device. In one exemplary embodiment, the at least one thermal path is disposed substantially centered over the thermal hot spots of the at one bottom-package semiconductor device.

In one exemplary embodiment, the at least one bottom-package semiconductor device comprises a backside metallization that is thermally coupled to the at least one thermal path.

In one exemplary embodiment, the top package further comprises a molding material layer formed on and between the plurality of top-package semiconductor devices, and the at least one thermal path extends through the molding material layer between the first top-package semiconductor device and the second top-package semiconductor device from the first side to the second side of the top package.

In one exemplary embodiment, the top package further comprises a thermal interface material (TIM) layer formed on a top surface of the molding material layer; and a heat slug formed on a top surface of the TIM layer.

In one exemplary embodiment, the at least one thermal path comprises at least one via extending through the top package from the first side to the top surface of the molding material layer, the at least one via being filled with a low thermal resistance material.

In one exemplary embodiment, the package substrate of the top package comprises at least one via extending through the package substrate and in alignment with the at least one thermal path, the at least one via extending through the package substrate being filled with a low thermal resistance material, and the at least one thermal path extending through the top package from the first side of the package substrate to the top surface of the molding material layer in alignment with the at least one via extending through the package substrate, the at least one heat slug being mounted on top of the package substrate or the at least one trench being filled with a low thermal resistance material.

In one exemplary embodiment, the at least one heat slug is mounted on top of the package substrate or the at least one trench is further filled with the low thermal resistance material.

Embodiments disclosed herein provide a semiconductor package comprising a bottom package and a top package. The bottom package comprises a bottom-package substrate comprising a first side and a second side; and at least one controller-type semiconductor device on the first side of the bottom-package substrate in which the at least one controller-type semiconductor device comprises a first side, a second side and a backside metallization on the first side of the controller-type semiconductor device. The top package is on the bottom package, and the top package comprises a first side and a second side; a package substrate disposed at the first side of the top package; a plurality of top-package semiconductor devices on the package substrate in which at least one top-package semiconductor device comprises a memory semiconductor device; a molding material layer formed on and between the plurality of top-package semiconductor devices; a thermal interface material (TIM) layer formed on a top surface of the molding material layer; and a heat slug formed on a top surface of the TIM layer and being thermally coupled to the TIM layer; and at least one thermal path disposed between a first top-package semiconductor device and a second top-package semiconductor device in which the thermal path extends from the first side of the top package through the package substrate to the TIM layer, and the thermal path is disposed over and is thermally coupled to the at least one bottom-package semiconductor device.

In one exemplary embodiment, the at least one thermal path comprises at least one via extending through the top package from the first side to the top surface of the molding material layer, the at least one via being filled with a low thermal resistance material. In one exemplary embodiment, the package substrate of the bottom package comprises at least one via extending through the package substrate and in alignment with the at least one thermal path, the at least one via extending through the package substrate being filled with a low thermal resistance material, and the at least one thermal path extending through the top package from the first side of the package substrate to the top surface of the molding material layer in alignment with the at least one via extending through the package substrate, the at least one heat slug being mounted on top of the top package substrate or the at least one trench being filled with a low thermal resistance material.

### BRIEF DESCRIPTION OF THE DRAWINGS

Example embodiments will be more clearly understood from the following detailed description taken in conjunction with the accompanying drawings. The Figures represent non-limiting, example embodiments as described herein.

FIG. 1A depicts a cross-section view of a first exemplary embodiment of a thermally enhanced package-on-package (POP) structure taken along line A-A′ in FIG. 1B according to the subject matter disclosed herein;

FIG. 1B depicts a cross-sectional view of the first exemplary embodiment of the top package taken along line B-B′ in FIG. 1A;

FIG. 2A depicts a cross-section view of a second exemplary embodiment of a thermally enhanced POP structure taken along line A-A′ in FIG. 2B according to the subject matter disclosed herein;

FIG. 2B depicts a cross-sectional view of the second exemplary embodiment of the top package taken along line B-B′ in FIG. 2A;

FIG. 3A depicts a cross-section view of a third exemplary embodiment of a thermally enhanced POP structure taken along line A-A′ in FIG. 3B according to the subject matter disclosed herein;

FIG. 3B depicts a cross-sectional view of the third exemplary embodiment of the top package taken along line B-B′ in FIG. 3A;

FIG. 4A depicts a cross-section view of a fourth exemplary embodiment of a thermally enhanced POP structure taken along line A-A′ in FIG. 4B according to the subject matter disclosed herein;

FIG. 4B depicts a cross-sectional view of the fourth exemplary embodiment of the top package taken along line B-B′ in FIG. 4A;

FIG. 5A depicts a cross-section view of a fifth exemplary embodiment of a thermally enhanced POP structure taken along line A-A′ in FIG. 5B according to the subject matter disclosed herein;

FIG. 5B depicts a cross-sectional view of the fifth exemplary embodiment of the top package taken along line B-B′ in FIG. 5A;

FIG. 6 depicts a flow diagram for an exemplary process for forming a thermally enhanced POP structure according to the subject matter disclosed herein;

FIG. 7 depicts an electronic device that comprises one or more thermally enhanced POP structures disclosed herein;

FIG. 8 depicts a memory system that comprises one or more thermally enhanced POP structures disclosed herein;

FIG. 9 depicts a block diagram illustrating an exemplary mobile device that comprises one or more thermally enhanced POP structures disclosed herein; and

FIG. 10 depicts a block diagram illustrating an exemplary computing system that comprises one or more thermally enhanced POP structures disclosed herein.

### DESCRIPTION OF EMBODIMENTS

The subject disclosed herein relates to thermally enhanced package-to-package (POP) structures. In exemplary embodiments, a thermally enhanced POP structure comprises a top package and a bottom package. According to the subject matter disclosed herein, the thermally enhanced POP provides an improved dissipation of the heat produced by semiconductor devices that are part of the bottom package. The enhancement is achieved by having thermal dissipation path in the top package. The path is formed by thermal vias/holes that are filled by low-thermal-resistance material, trenches that are filled by low-thermal-resistance material, planar carved heat slug that is mounted on the package substrate, 3D carved heat slug that is mounted on the package substrate, or discrete components that are mounted on the package substrate. A thermal interface material is formed in between the top package and the bottom package. A back-side metallization or a polymer is formed on a semiconductor device on the bottom package. In one exemplary embodiment, the top package comprises Dynamic Random Access Memory (DRAM) semiconductor devices, and the bottom package comprises a controller chip semiconductor device.

Various exemplary embodiments will be described more fully hereinafter with reference to the accompanying drawings, in which some exemplary embodiments are shown. As used herein, the word “exemplary” means “serving as an example, instance, or illustration.” Any embodiment described herein as “exemplary” is not to be construed as necessarily preferred or advantageous over other embodiments. The subject matter disclosed herein may, however, be embodied in many different forms and should not be construed as limited to the exemplary embodiments set forth herein. Rather, the exemplary embodiments are provided so that this description will be thorough and complete, and will fully convey the scope of the claimed subject matter to those skilled in the art. In the drawings, the sizes and relative sizes of layers and regions may be exaggerated for clarity.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein, but are to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the claimed subject matter.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

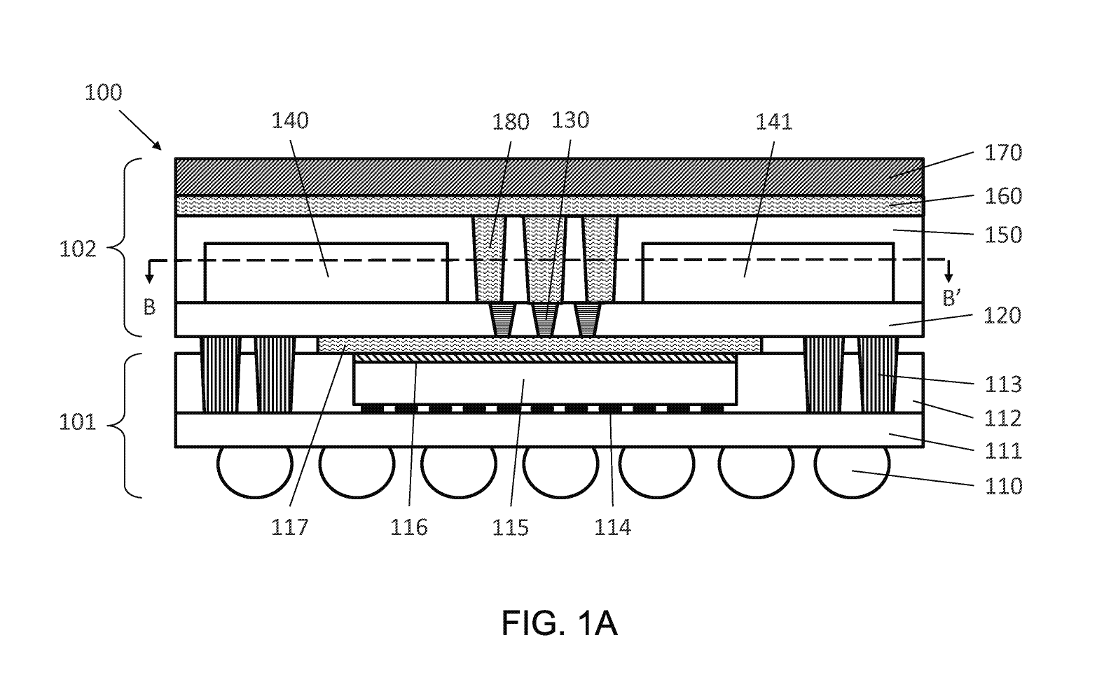

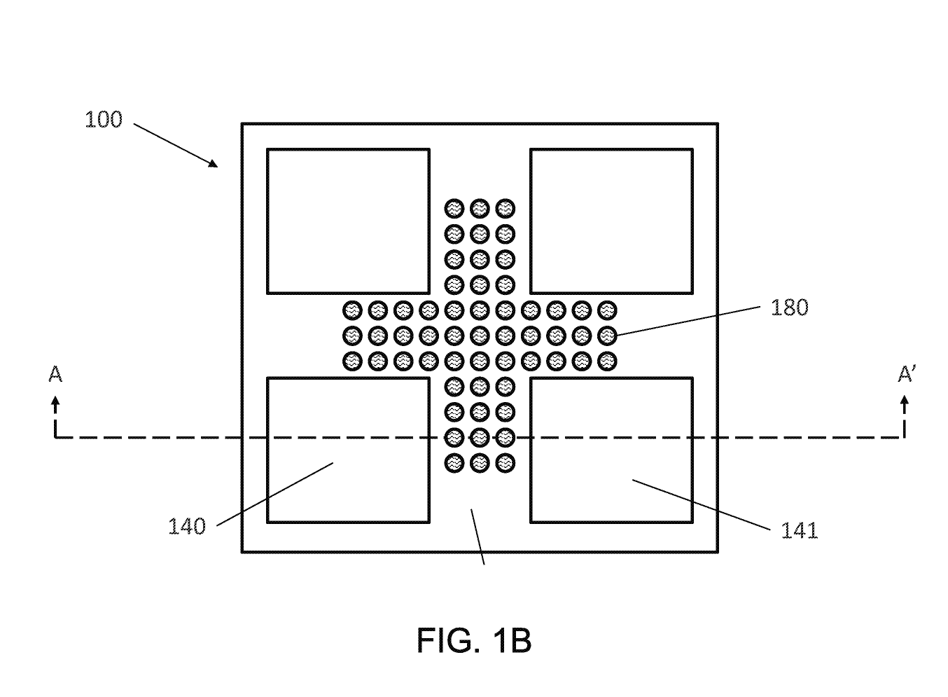

FIG. 1A depicts a cross-section view of a first exemplary embodiment of a thermally enhanced package-on-package (POP) structure 100 taken along line A-A′ in FIG. 1B according to the subject matter disclosed herein. FIG. 1B depicts a cross-sectional view of the first exemplary embodiment of a thermally enhanced POP structure 100 taken along line B-B′ in FIG. 1A.

POP structure 100 comprises a bottom package 101 and a top package 102 mounted on the bottom package 101. The bottom package 101 comprises a package substrate 111 and a semiconductor device 115 mounted on the package substrate 111. The package substrate 111 is connected to the system by a ball grid array 110. In one exemplary embodiment, the semiconductor device 115 comprises a processor semiconductor device, a controller semiconductor device, a memory controller semiconductor device, or the like. In an alternative exemplary embodiment, the bottom package 101 could comprise a plurality of semiconductor devices mounted on the package substrate 111 with bumps 114. In an alternative exemplary embodiment (not shown), the bottom package 101 could only comprise a plurality of semiconductor devices with redistribution layer, but without the package substrate 111.

The package substrate 111 in the bottom package 101 may comprise a multilayer printed circuit board (PCB) or a redistribution layer (RDL) with one or more upper substrate pads (not shown) and one or more lower substrate pads (not shown).

The semiconductor device 115 may comprise a semiconductor substrate with one or more bonding pads (not shown) disposed on a lower surface of the semiconductor substrate, and a backside metallization 116 disposed on an upper surface of the semiconductor substrate. In an alternative exemplary embodiment, the semiconductor device 115 may comprise a polymer instead of the backside metallization 116.

A thermal interface material (TIM) layer 117 is disposed between the bottom package 101 and the top package 102 to cover a selected portion of the top surface of the semiconductor device 115 with backside metallization 116.

Balls 110 may be disposed on lower substrate pads on the package substrate 111. The balls 110 may be electrically connected to an external circuit board (not shown). The balls 110 may include a solder material.

The bottom package 101 may further include a molding material 112 that covers the side surfaces of semiconductor device 115 and one or more package vias 113 connecting the upper pads of the package substrate 111 and the bottom pads of the top package 102. The molding material 112 may comprise an epoxy molding compound, or the like.

A first exemplary embodiment of the top package 102 comprises a package substrate 120, a first semiconductor device 140 and a second semiconductor device 141. The first semiconductor device 140 and the second semiconductor device 141 are mounted on the package substrate 120. In one exemplary embodiment, the first and second semiconductor devices comprise Dynamic Random Access Memory (DRAM). In an alternative exemplary embodiment, the top package 102 could comprise more semiconductor devices than depicted in FIGS. 1A and 1B.

In one exemplary embodiment, the package substrate 120 may comprise a multilayer printed circuit board (PCB) with one or more upper substrate pads (not shown) and one or more lower substrate pads (not shown). In an alternative exemplary embodiment (not shown), the top package 102 could only comprise a plurality of semiconductor devices with redistribution layer, but without the package substrate 120.

The first and second semiconductor devices 140 may be wire-bonded or flip-chip bonded.

The top package 102 may further include a molding material 150 that covers the first semiconductor device 140 and the second semiconductor device 141. The molding material 150 may comprise an epoxy molding compound, or the like.

The package substrate 120 also comprises one or more thermal vias 130 that may be filled with a thermally conductive material (i.e., low thermal resistance), such as, but not limited to, copper and/or a metallic material. In one exemplary embodiment, the top package 102 may comprise one or more vias 180 that are formed through molding material 150 between the first semiconductor device 140 and the second semiconductor device 141. Vias 180 may be filled with a thermally conductive material (i.e., low thermal resistance), such as, but not limited to, a thermal interface material (TIM), solder, a wire, and/or a metallic material. The thermally conductive material in the one or more vias 180 is thermally coupled to the one or more vias 130.

A thermal interface material (TIM) layer 160 is formed on the top surface of the molding material 150 and thermal vias 180. A heat slug 170 is formed on the TIM layer 160. The heat slug 170 is a metal plate made by copper, aluminum, or the like.

A thermal path is formed between the semiconductor device 115 and the heat slug 170 by the backside metallization 116 disposed on an upper surface of the semiconductor device 115, the TIM layer 117, the vias 130, the vias 180, and the TIM layer 160. In alternative exemplary embodiments in which the semiconductor device 115 does not comprise the backside metallization 116, a thermal path is formed between the semiconductor device 115 and the heat slug 170 by the TIM layer 117, the vias 130, the vias 180, and the TIM layer 160.

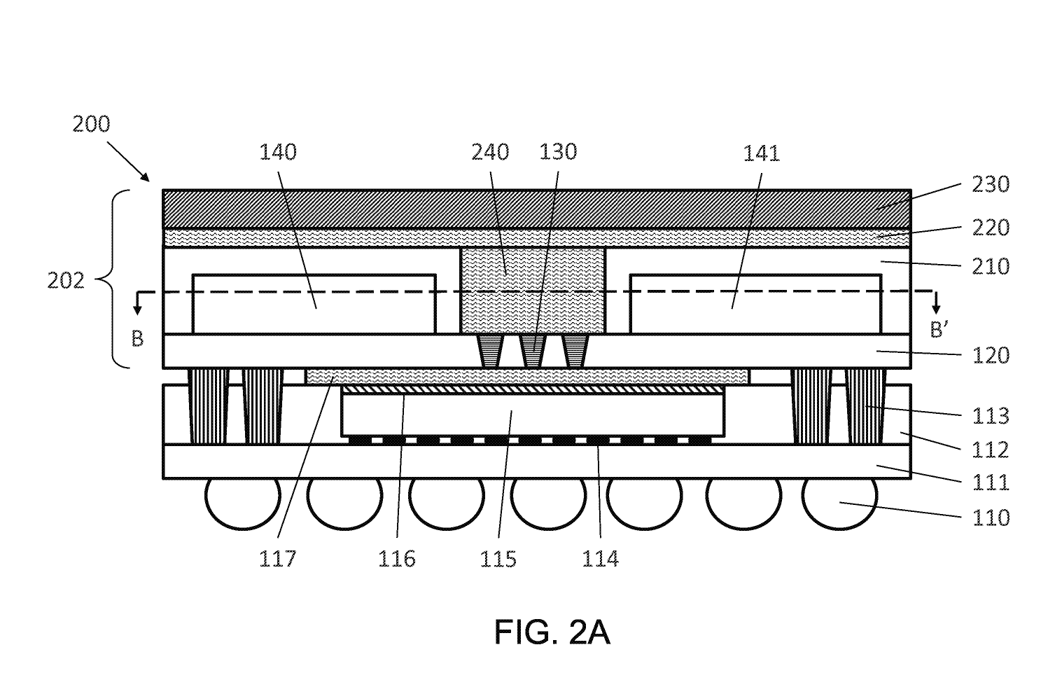

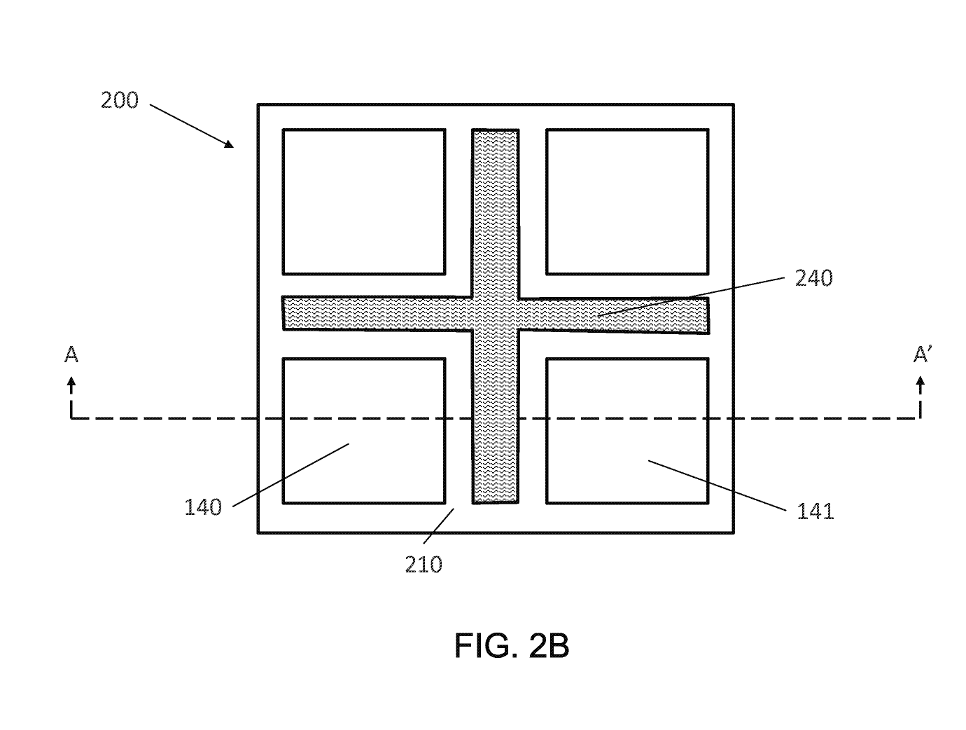

FIG. 2A depicts a cross-section view of a second exemplary embodiment of a thermally enhanced POP structure 200 taken along line A-A′ in FIG. 2B according to the subject matter disclosed herein. FIG. 2B depicts a cross-sectional view of the second exemplary embodiment the top package 200 taken along line B-B′ in FIG. 2A.

POP structure 100 comprises a bottom package 101 and a top package 202 mounted on the bottom package 101. The bottom package 101 comprises a package substrate 111 and a semiconductor device 115 mounted on the package substrate 111. The package substrate 111 is connected to the system by a ball grid array 110. In one exemplary embodiment, the semiconductor device 115 comprises a processor semiconductor device, a controller semiconductor device, a memory controller semiconductor device, or the like. In an alternative exemplary embodiment, the bottom package 101 could comprise a plurality of semiconductor devices mounted on the package substrate 111 with bumps 114. In an alternative exemplary embodiment (not shown), the bottom package 101 could only comprise a plurality of semiconductor devices with redistribution layer, but without the package substrate 111.

The package substrate 111 in the bottom package 101 may comprise a multilayer printed circuit board (PCB) or a redistribution layer (RDL) with one or more upper substrate pads (not shown) and one or more lower substrate pads (not shown).

The semiconductor device 115 may comprise a semiconductor substrate with one or more bonding pads (not shown) disposed on a lower surface of the semiconductor substrate, and a backside metallization 116 disposed on an upper surface of the semiconductor substrate. In an alternative exemplary embodiment, the semiconductor device 115 may comprise a polymer instead of the backside metallization 116.

A thermal interface material (TIM) layer 117 is disposed between the bottom package 101 and the top package 102 to cover a selected portion of the top surface of the semiconductor device 115 with backside metallization 116.

Balls 110 may be disposed on lower substrate pads on the package substrate 111. The balls 110 may be electrically connected to an external circuit board (not shown). The balls 110 may include a solder material.

The bottom package 101 may further include a molding material 112 that covers the side surfaces of semiconductor device 115 and one or more package vias 113 connecting the upper pads of the package substrate 111 and the bottom pads of the top package 102. The molding material 112 may comprise an epoxy molding compound, or the like.

A second exemplary embodiment of the top package 202 comprises a package substrate 120, a first semiconductor device 140 and a second semiconductor device 141. The first semiconductor device 140 and the second semiconductor device 141 are mounted on the package substrate 120. In one exemplary embodiment, the first and second semiconductor devices comprise Dynamic Random Access Memory (DRAM). In an alternative exemplary embodiment, the top package 202 could comprise more semiconductor devices than depicted in FIGS. 2A and 2B.

In one exemplary embodiment, the package substrate 120 may comprise a multilayer printed circuit board (PCB) with one or more upper substrate pads (not shown) and one or more lower substrate pads (not shown). In an alternative exemplary embodiment (not shown), the top package 202 could only comprise a plurality of semiconductor devices with redistribution layer, but without the package substrate 120.

The first and second semiconductor devices 140 may be wire-bonded or flip-chip bonded.

The top package 202 may further include a molding material 210 that covers the first semiconductor device 140 and the second semiconductor device 141. The molding material 210 may comprise an epoxy molding compound, or the like.

The package substrate 120 also comprises one or more thermal vias 130 that may be filled with a thermally conductive material (i.e., low thermal resistance), such as, but not limited to, copper and/or a metallic material. In one exemplary embodiment, the top package 202 may comprise one or more trenches 240 that are formed between the first semiconductor device 140 and the second semiconductor device 141. The one or more trenches 240 may be filled with a thermally conductive material (i.e., low thermal resistance), such as, but not limited to, TIM, solder, and/or a metallic material. The thermally conductive material in the one or more trenches 240 is thermally coupled to the one or more vias 130.

A TIM layer 220 is formed on the top surface of the molding material 210 and thermal trenches 240. A heat slug 230 is formed on the TIM layer 220. The heat slug 230 is a metal plate made by copper, aluminum, or the like.

A thermal path is formed between the semiconductor device 115 and the heat slug 230 by the backside metallization 116 disposed on an upper surface of the semiconductor device 115, the TIM layer 117, the vias 130, the trenches 240, and the TIM layer 220. In alternative exemplary embodiments in which the semiconductor device 115 does not comprise the backside metallization 116, a thermal path is formed between the semiconductor device 115 and the heat slug 230 by the TIM layer 117, the vias 130, the trenches 240, and the TIM layer 220.

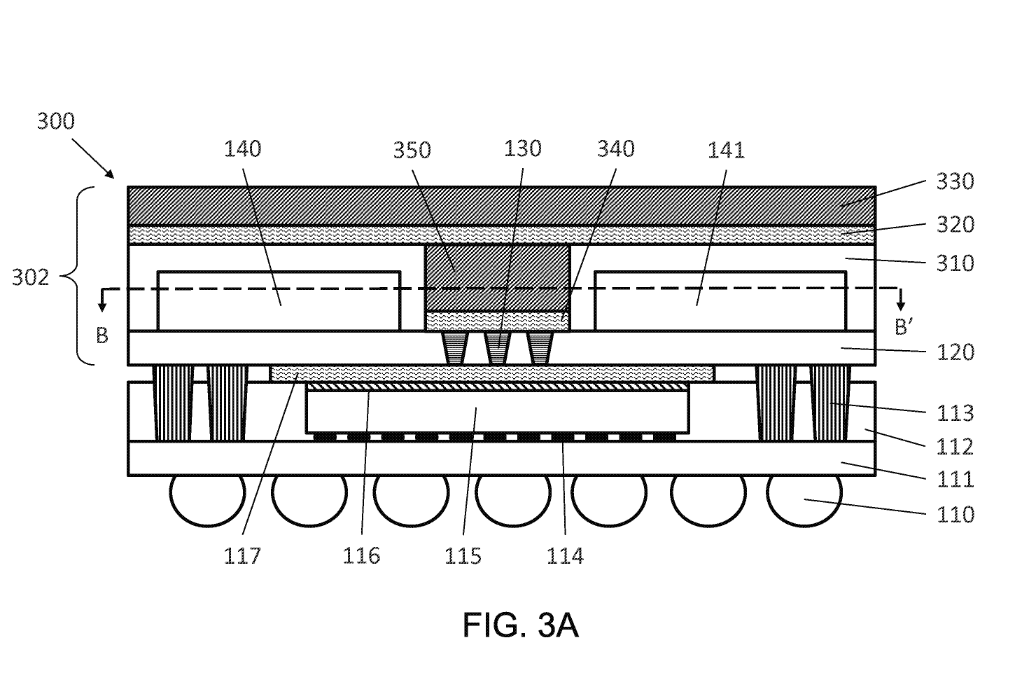

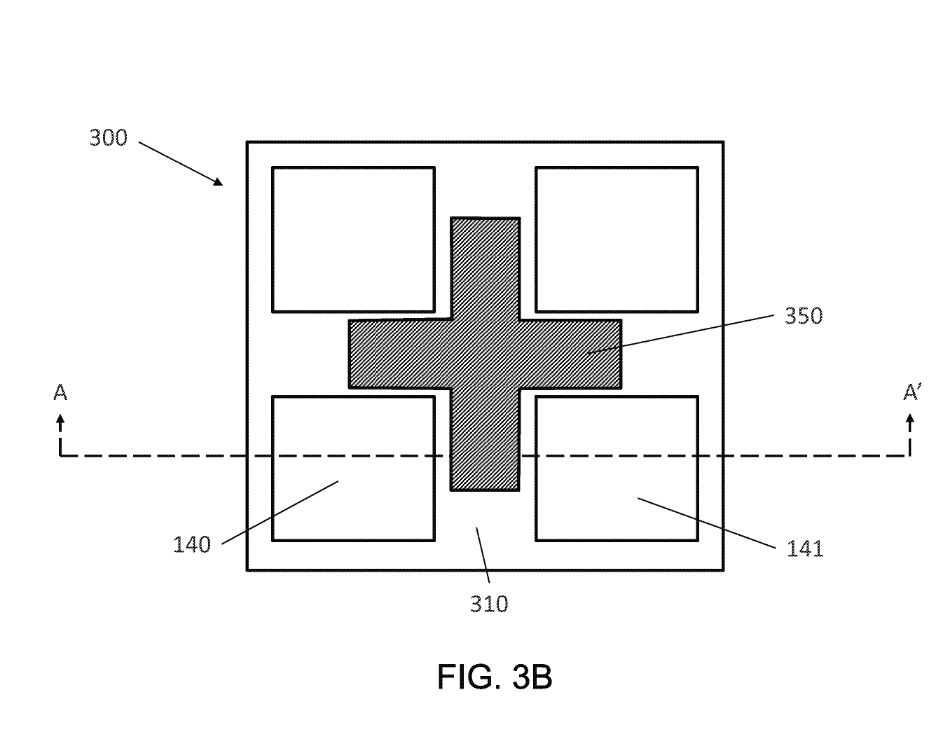

FIG. 3A depicts a cross-section view of a third exemplary embodiment of a thermally enhanced POP structure 300 taken along line A-A′ in FIG. 3B according to the subject matter disclosed herein. FIG. 3B depicts a cross-sectional view of the third exemplary embodiment of a thermally enhanced POP structure 300 taken along line B-B′ in FIG. 3A.

POP structure 300 comprises a bottom package 101 and a top package 302 mounted on the bottom package 101. The bottom package 101 comprises a package substrate 111 and a semiconductor device 115 mounted on the package substrate 111. The package substrate 111 is connected to the system by a ball grid array 110. In one exemplary embodiment, the semiconductor device 115 comprises a processor semiconductor device, a controller semiconductor device, a memory controller semiconductor device, or the like. In an alternative exemplary embodiment, the bottom package 101 could comprise a plurality of semiconductor devices mounted on the package substrate 111 with bumps 114. In an alternative exemplary embodiment (not shown), the bottom package 101 could only comprise a plurality of semiconductor devices with redistribution layer, but without the package substrate 111.

The package substrate 111 in the bottom package 101 may comprise a multilayer printed circuit board (PCB) or a redistribution layer (RDL) with one or more upper substrate pads (not shown) and one or more lower substrate pads (not shown).

The semiconductor device 115 may comprise a semiconductor substrate with one or more bonding pads (not shown) disposed on a lower surface of the semiconductor substrate, and a backside metallization 116 disposed on an upper surface of the semiconductor substrate. In an alternative exemplary embodiment, the semiconductor device 115 may comprise a polymer instead of the backside metallization 116.

A thermal interface material (TIM) layer 117 is disposed between the bottom package 101 and the top package 102 to cover a selected portion of the top surface of the semiconductor device 115 with backside metallization 116.

Balls 110 may be disposed on lower substrate pads on the package substrate 111. The balls 110 may be electrically connected to an external circuit board (not shown). The balls 110 may include a solder material.

The bottom package 101 may further include a molding material 112 that covers the side surfaces of semiconductor device 115 and one or more package vias 113 connecting the upper pads of the package substrate 111 and the bottom pads of the top package 102. The molding material 112 may comprise an epoxy molding compound, or the like.

A third exemplary embodiment of the top package 302 comprises a package substrate 120, a first semiconductor device 140 and a second semiconductor device 141. The first semiconductor device 140 and the second semiconductor device 141 are mounted on the package substrate 120. In one exemplary embodiment, the first and second semiconductor devices comprise Dynamic Random Access Memory (DRAM). In an alternative exemplary embodiment, the top package 302 could comprise more semiconductor devices than depicted in FIGS. 3A and 3B.

In one exemplary embodiment, the package substrate 120 may comprise a multilayer printed circuit board (PCB) with one or more upper substrate pads (not shown) and one or more lower substrate pads (not shown). In an alternative exemplary embodiment (not shown), the top package 302 could only comprise a plurality of semiconductor devices with redistribution layer, but without the package substrate 120.

The first and second semiconductor devices 140 may be wire-bonded or flip-chip bonded.

The top package 302 may further include a molding material 310 that covers the first semiconductor device 140 and the second semiconductor device 141. The molding material 310 may comprise an epoxy molding compound, or the like.

The package substrate 120 also comprises one or more thermal vias 130 that may be filled with a thermally conductive material (i.e., low thermal resistance), such as, but not limited to, copper and/or a metallic material. In one exemplary embodiment, the top package 302 may comprise at least one carved heat slug 350 being mounted on top of the package substrate 120 by thermally conductive adhesive 340 and between the first semiconductor device 140 and the second semiconductor device 141. The carved heat slug 350 is mounted to be substantially centered over the thermal hot spots of a semiconductor device 115. The thermally conductive heat slug 350 is thermally coupled to the one or more vias 130. The heat slug 350 is a carved metal plate made by copper, aluminum, or the like.

A TIM layer 320 is formed on the top surface of the molding material 310 and the heat slug 350. A heat slug 330 is formed on the TIM layer 320. The heat slug 330 is a metal plate made by copper, aluminum, or the like.

A thermal path is formed between the semiconductor device 115 and the heat slug 330 by the backside metallization 116 disposed on an upper surface of the semiconductor device 115, the TIM layer 117, the vias 130, the heat slug 350, and the TIM layer 320. In alternative exemplary embodiments in which the semiconductor device 115 does not comprise the backside metallization 116, a thermal path is formed between the semiconductor device 115 and the heat slug 330 by the TIM layer 117, the vias 130, the heat slug 350, and the TIM layer 320.

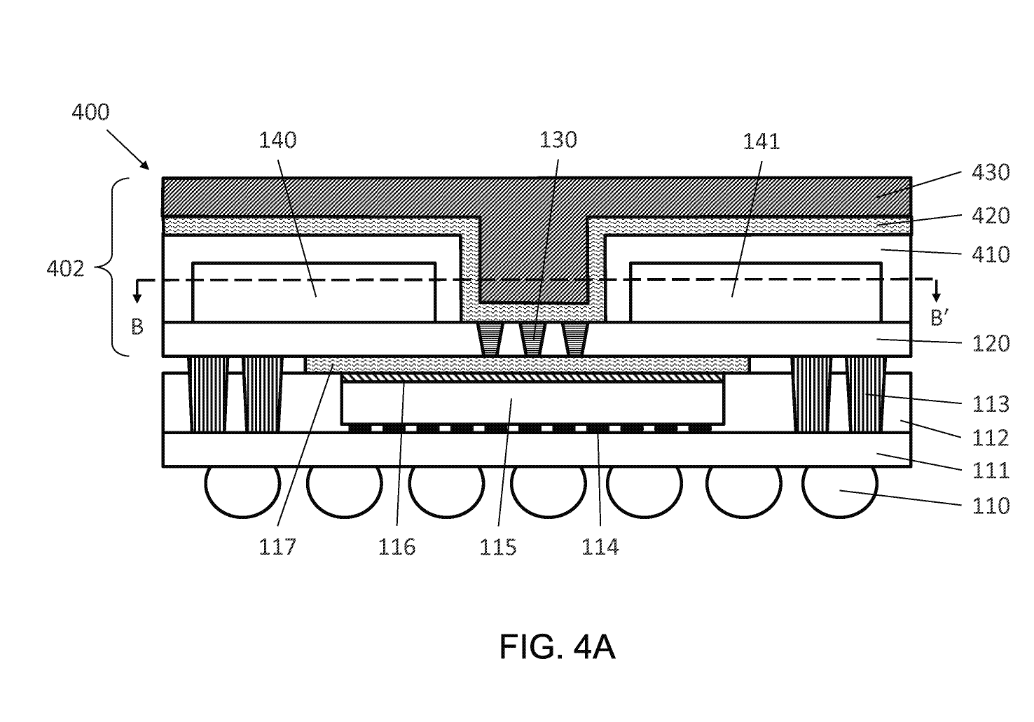

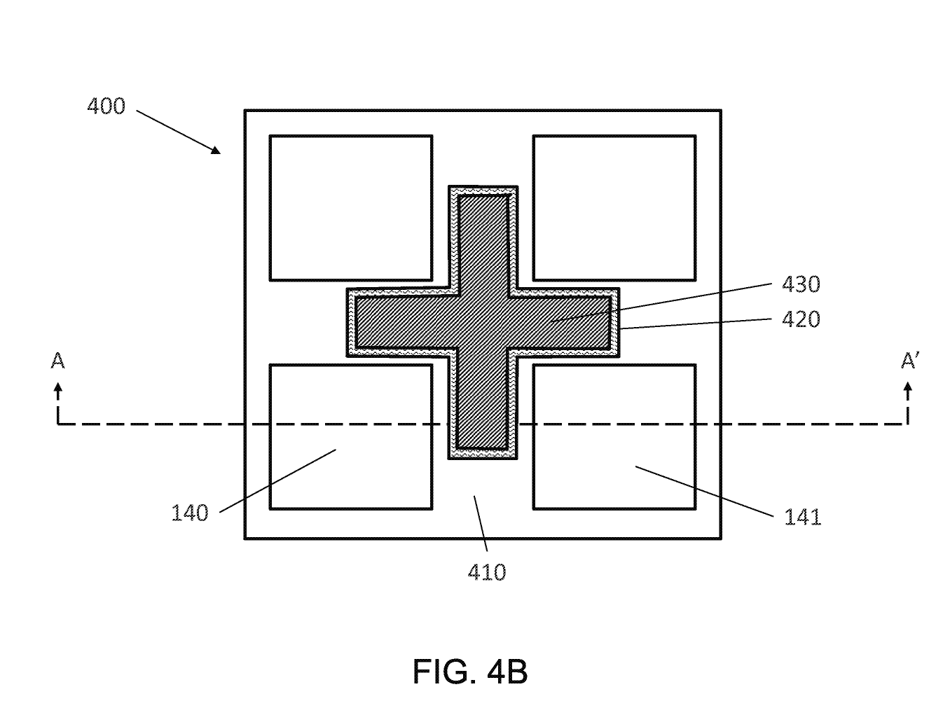

FIG. 4A depicts a cross-section view of a fourth exemplary embodiment of a thermally enhanced POP structure 400 taken along line A-A′ in FIG. 4B according to the subject matter disclosed herein. FIG. 4B depicts a cross-sectional view of the third exemplary embodiment of a thermally enhanced POP structure 400 taken along line B-B′ in FIG. 4A.

POP structure 400 comprises a bottom package 101 and a top package 402 mounted on the bottom package 101. The bottom package 101 comprises a package substrate 111 and a semiconductor device 115 mounted on the package substrate 111. The package substrate 111 is connected to the system by a ball grid array 110. In one exemplary embodiment, the semiconductor device 115 comprises a processor semiconductor device, a controller semiconductor device, a memory controller semiconductor device, or the like. In an alternative exemplary embodiment, the bottom package 101 could comprise a plurality of semiconductor devices mounted on the package substrate 111 with bumps 114. In an alternative exemplary embodiment (not shown), the bottom package 101 could only comprise a plurality of semiconductor devices with redistribution layer, but without the package substrate 111.

The package substrate 111 in the bottom package 101 may comprise a multilayer printed circuit board (PCB) or a redistribution layer (RDL) with one or more upper substrate pads (not shown) and one or more lower substrate pads (not shown).

The semiconductor device 115 may comprise a semiconductor substrate with one or more bonding pads (not shown) disposed on a lower surface of the semiconductor substrate, and a backside metallization 116 disposed on an upper surface of the semiconductor substrate. In an alternative exemplary embodiment, the semiconductor device 115 may comprise a polymer instead of the backside metallization 116.

A thermal interface material (TIM) layer 117 is disposed between the bottom package 101 and the top package 102 to cover a selected portion of the top surface of the semiconductor device 115 with backside metallization 116.

Balls 110 may be disposed on lower substrate pads on the package substrate 111. The balls 110 may be electrically connected to an external circuit board (not shown). The balls 110 may include a solder material.

The bottom package 101 may further include a molding material 112 that covers the side surfaces of semiconductor device 115 and one or more package vias 113 connecting the upper pads of the package substrate 111 and the bottom pads of the top package 102. The molding material 112 may comprise an epoxy molding compound, or the like.

A fourth exemplary embodiment of the top package 402 comprises a package substrate 120, a first semiconductor device 140 and a second semiconductor device 141. The first semiconductor device 140 and the second semiconductor device 141 are mounted on the package substrate 120. In one exemplary embodiment, the first and second semiconductor devices comprise Dynamic Random Access Memory (DRAM). In an alternative exemplary embodiment, the top package 402 could comprise more semiconductor devices than depicted in FIGS. 4A and 4B.

In one exemplary embodiment, the package substrate 120 may comprise a multilayer printed circuit board (PCB) with one or more upper substrate pads (not shown) and one or more lower substrate pads (not shown). In an alternative exemplary embodiment (not shown), the top package 402 could only comprise a plurality of semiconductor devices with redistribution layer, but without the package substrate 120.

The first and second semiconductor devices 140 may be wire-bonded or flip-chip bonded.

The top package 402 may further include a molding material 310 that covers the first semiconductor device 140 and the second semiconductor device 141. The molding material 410 may comprise an epoxy molding compound, or the like.

The package substrate 120 also comprises one or more thermal vias 130 that may be filled with a thermally conductive material (i.e., low thermal resistance), such as, but not limited to, copper and/or a metallic material.

A TIM layer 420 is formed on the top surface of the molding material 410. A carved heat slug 430 is formed on the TIM layer 420. The heat slug 430 is a three-dimensional carved metal plate made by copper, aluminum, or the like. The heat slug 430 is thermally coupled to the one or more vias 130.

A thermal path is formed between the semiconductor device 115 and the heat slug 430 by the backside metallization 116 disposed on an upper surface of the semiconductor device 115, the TIM layer 117, the vias 130, and the TIM layer 320. In alternative exemplary embodiments in which the semiconductor device 115 does not comprise the backside metallization 116, a thermal path is formed between the semiconductor device 115 and the heat slug 430 by the TIM layer 117, the vias 130, and the TIM layer 420.

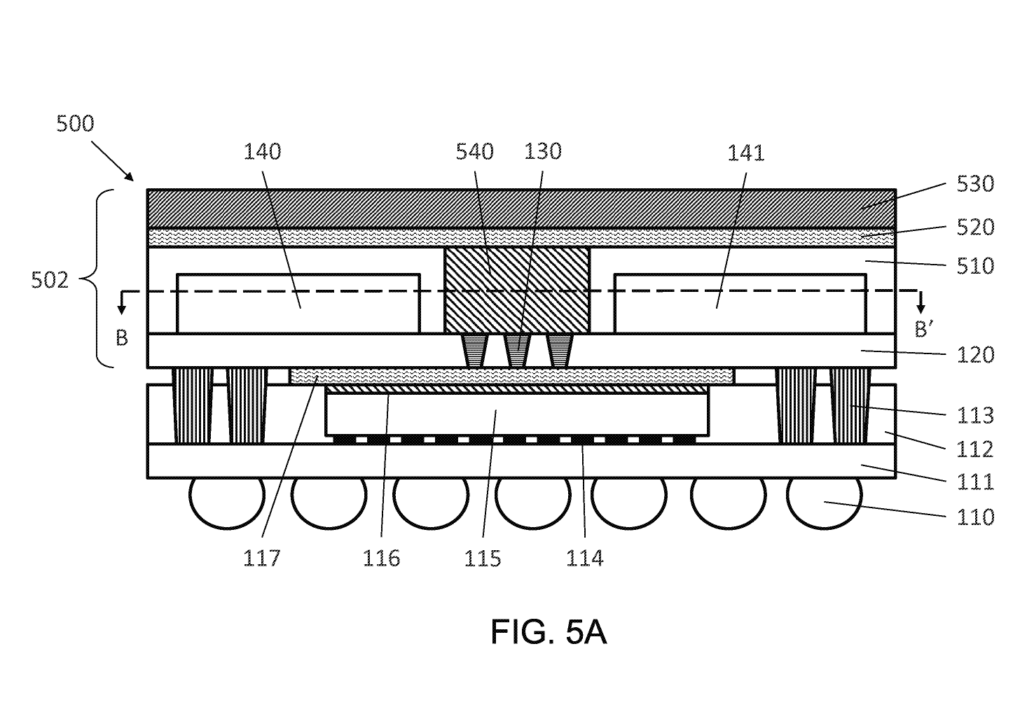

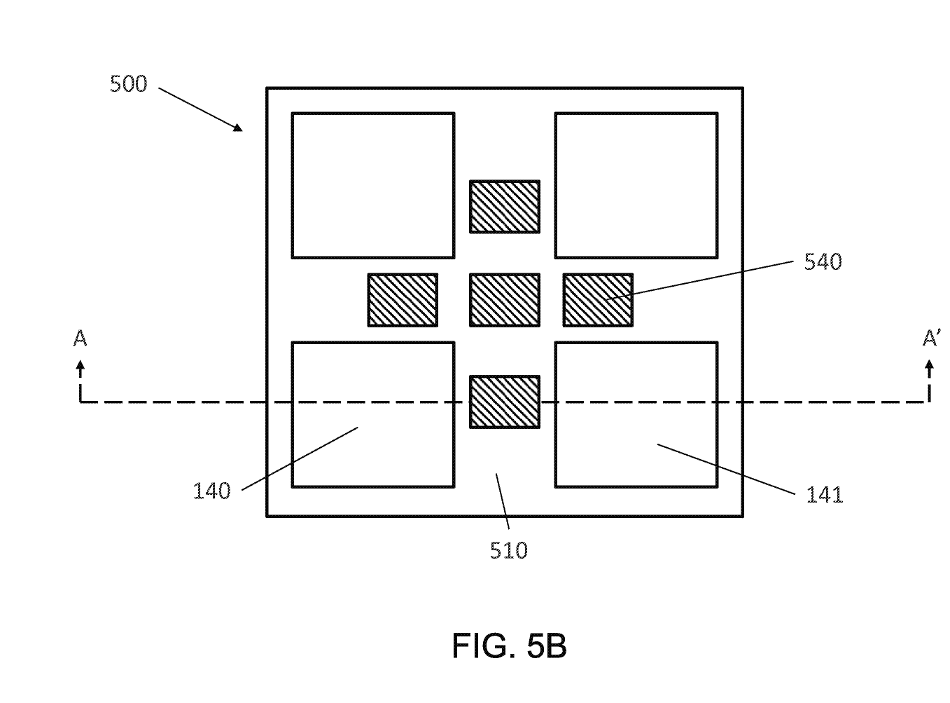

FIG. 5A depicts a cross-section view of a fifth exemplary embodiment of a thermally enhanced POP structure 500 taken along line A-A′ in FIG. 5B according to the subject matter disclosed herein. FIG. 5B depicts a cross-sectional view of the fifth exemplary embodiment of a thermally enhanced POP structure 500 taken along line B-B′ in FIG. 5A.

POP structure 500 comprises a bottom package 101 and a top package 502 mounted on the bottom package 101. The bottom package 101 comprises a package substrate 111 and a semiconductor device 115 mounted on the package substrate 111. The package substrate 111 is connected to the system by a ball grid array 110. In one exemplary embodiment, the semiconductor device 115 comprises a processor semiconductor device, a controller semiconductor device, a memory controller semiconductor device, or the like. In an alternative exemplary embodiment, the bottom package 101 could comprise a plurality of semiconductor devices mounted on the package substrate 111 with bumps 114. In an alternative exemplary embodiment (not shown), the bottom package 101 could only comprise a plurality of semiconductor devices with redistribution layer, but without the package substrate 111.

The package substrate 111 in the bottom package 101 may comprise a multilayer printed circuit board (PCB) or a redistribution layer (RDL) with one or more upper substrate pads (not shown) and one or more lower substrate pads (not shown).

The semiconductor device 115 may comprise a semiconductor substrate with one or more bonding pads (not shown) disposed on a lower surface of the semiconductor substrate, and a backside metallization 116 disposed on an upper surface of the semiconductor substrate. In an alternative exemplary embodiment, the semiconductor device 115 may comprise a polymer instead of the backside metallization 116.

A thermal interface material (TIM) layer 117 is disposed between the bottom package 101 and the top package 102 to cover a selected portion of the top surface of the semiconductor device 115 with backside metallization 116.

Balls 110 may be disposed on lower substrate pads on the package substrate 111. The balls 110 may be electrically connected to an external circuit board (not shown). The balls 110 may include a solder material.

The bottom package 101 may further include a molding material 112 that covers the side surfaces of semiconductor device 115 and one or more package vias 113 connecting the upper pads of the package substrate 111 and the bottom pads of the top package 102. The molding material 112 may comprise an epoxy molding compound, or the like.

A fifth exemplary embodiment of the top package 502 comprises a package substrate 120, a first semiconductor device 140 and a second semiconductor device 141. The first semiconductor device 140 and the second semiconductor device 141 are mounted on the package substrate 120. In one exemplary embodiment, the first and second semiconductor devices comprise Dynamic Random Access Memory (DRAM). In an alternative exemplary embodiment, the top package 502 could comprise more semiconductor devices than depicted in FIGS. 5A and 5B.

In one exemplary embodiment, the package substrate 120 may comprise a multilayer printed circuit board (PCB) with one or more upper substrate pads (not shown) and one or more lower substrate pads (not shown). In an alternative exemplary embodiment (not shown), the top package 502 could only comprise a plurality of semiconductor devices with redistribution layer, but without the package substrate 120.

The first and second semiconductor devices 140 may be wire-bonded or flip-chip bonded.

The top package 502 may further include a molding material 510 that covers the first semiconductor device 140 and the second semiconductor device 141. The molding material 510 may comprise an epoxy molding compound, or the like.

The package substrate 120 also comprises one or more thermal vias 130 that may be filled with a thermally conductive material (i.e., low thermal resistance), such as, but not limited to, copper and/or a metallic material. In one exemplary embodiment, the top package 502 may comprise one or more discrete components 540 being mounted on top of the package substrate 120 by thermally conductive solder (not shown) and between the first semiconductor device 140 and the second semiconductor device 141. The components 540 are thermally coupled to the one or more vias 130.

A TIM layer 520 is formed on the top surface of the molding material 510 and the heat slug 530. A heat slug 530 is formed on the TIM layer 520. The heat slug 530 is a metal plate made by copper, aluminum, or the like.

A thermal path is formed between the semiconductor device 115 and the heat slug 530 by the backside metallization 116 disposed on an upper surface of the semiconductor device 115, the TIM layer 117, the vias 130, the discrete components 540, and the TIM layer 520. In alternative exemplary embodiments in which the semiconductor device 115 does not comprise the backside metallization 116, a thermal path is formed between the semiconductor device 115 and the heat slug 530 by the TIM layer 117, the vias 130, the discrete components 540, and the TIM layer 520.

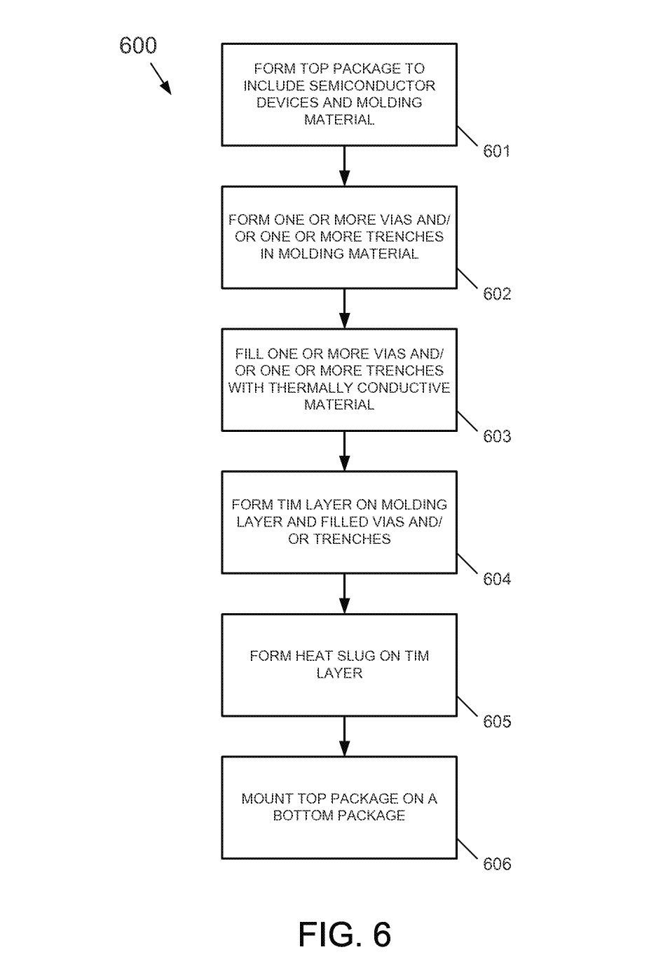

FIG. 6 depicts a flow diagram for an exemplary process 600 for forming a thermally enhanced POP structure according to the subject matter disclosed herein. With reference to FIGS. 1-5, at operation 601, a top package has been formed using well-known techniques in which a molding material has been formed on the semiconductor devices of the top package. At operation 602, a portion of the molding material has been removed by forming one or more vias and/or by forming one or more trenches to expose a top surface of a package substrate. In one exemplary embodiment, prior to removing the molding materials, vias have already been formed in the package substrate using a well-known technique, and a well-known technique has been used to fill the vias with a thermally conductive material, such as, but not limited to, thermal interface material (TIM), solder and/or a metallic material. In another exemplary embodiment, vias are formed in the exposed package substrate a well-known technique, and a well-known technique is used to fill the vias with a thermally conductive material, such as, but not limited to, thermal interface material (TIM), solder and/or a metallic material.

At operation 603, the one or more vias and/or the one or more trenches form in operation 602 are filled using a well-known technique with a thermally conductive material (i.e., low thermal resistance), such as, but not limited to, a thermal interface material (TIM), solder, a wire, a printed circuit board (PCB), a multilayer ceramic (MLC) and/or a metallic material.

At operation 604, a TIM layer is formed on the top surface of the molding material and the tops of the one or more vias and/or the one or more trenches that have been filed with the thermally conductive material. At operation 605, a heat slug is formed on the TIM layer formed in operation 604. At operation 606, the top package is mounted on a bottom package using a well-known technique, thereby forming a thermal path between a semiconductor device thermally coupled to the vias in the package substrate of the top package and the heat slug formed in operation 605 after the top package is mounted on a bottom package in according with the exemplary embodiments disclosed herein.

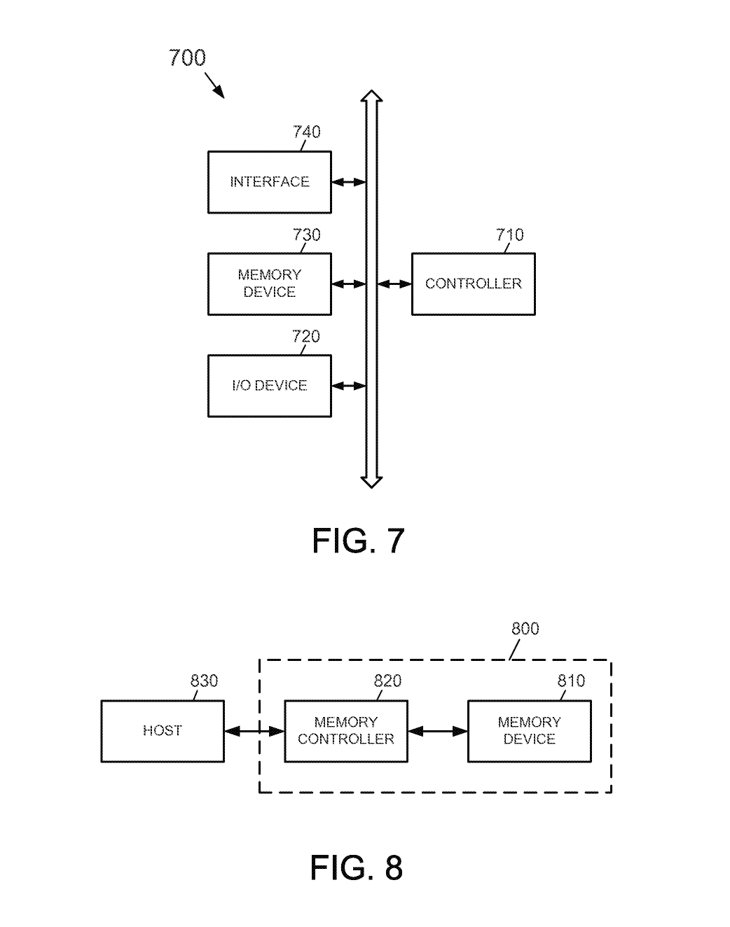

FIG. 7, for example, depicts an electronic device 700 that comprises one or more thermally enhanced POP structures disclosed herein. Electronic device 700 may be used in, but not limited to, a computing device, a server system, a personal digital assistant (PDA), a laptop computer, a mobile computer, a web tablet, a wireless phone, a cell phone, a smart phone, a digital music player, or a wireline or wireless electronic device. The electronic device 700 may comprise a controller 710, an input/output device 720 such as, but not limited to, a keypad, a keyboard, a display, or a touch-screen display, a memory 730, and a wireless interface 740 that are coupled to each other through a bus 750. The controller 710 may comprise, for example, at least one microprocessor, at least one digital signal process, at least one microcontroller, or the like. The memory 730 may be configured to store a command code to be used by the controller 710 or a user data. The electronic device 700 may use a wireless interface 740 configured to transmit data to or receive data from a wireless communication network using a RF signal. The wireless interface 640 may include, for example, an antenna, a wireless transceiver and so on. The electronic system 700 may be used in a communication interface protocol of a communication system, such as, but not limited to, Code Division Multiple Access (CDMA), Global System for Mobile Communications (GSM), North American Digital Communications (NADC), Extended Time Division Multiple Access (E-TDMA), Wideband CDMA (WCDMA), CDMA2000, Wi-Fi, Municipal Wi-Fi (Muni Wi-Fi), Bluetooth, Digital Enhanced Cordless Telecommunications (DECT), Wireless Universal Serial Bus (Wireless USB), Fast low-latency access with seamless handoff Orthogonal Frequency Division Multiplexing (Flash-OFDM), IEEE 802.20, General Packet Radio Service (GPRS), iBurst, Wireless Broadband (WiBro), WiMAX, WiMAX-Advanced, Universal Mobile Telecommunication Service—Time Division Duplex (UMTS-TDD), High Speed Packet Access (HSPA), Evolution Data Optimized (EVDO), Long Term Evolution-Advanced (LTE-Advanced), Multichannel Multipoint Distribution Service (MMDS), and so forth.

FIG. 8 depicts a memory system 800 that comprises one or more thermally enhanced POP structures disclosed herein. The memory system 800 may comprise a memory device 810 for storing large amounts of data and a memory controller 820. The memory controller 820 controls the memory device 810 to read data stored in the memory device 810 or to write data into the memory device 810 in response to a read/write request of a host 830. The memory controller 830 may include an address-mapping table for mapping an address provided from the host 830 (e.g., a mobile device or a computer system) into a physical address of the memory device 810.

The exemplary thermally enhanced POP structures disclosed herein may be encapsulated using various and diverse packaging techniques. For example, the thermally enhanced POP structures disclosed herein may be encapsulated using any one of a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic quad flat package (PQFP) technique, a thin quad flat package (TQFP) technique, a small outline package (SOIC) technique, a shrink small outline package (SSOP) technique, a thin small outline package (TSOP) technique, a thin quad flat package (TQFP) technique, a system in package (SIP) technique, a multi-chip package (MCP) technique, a wafer-level fabricated package (WFP) technique and a wafer-level processed stack package (WSP) technique.

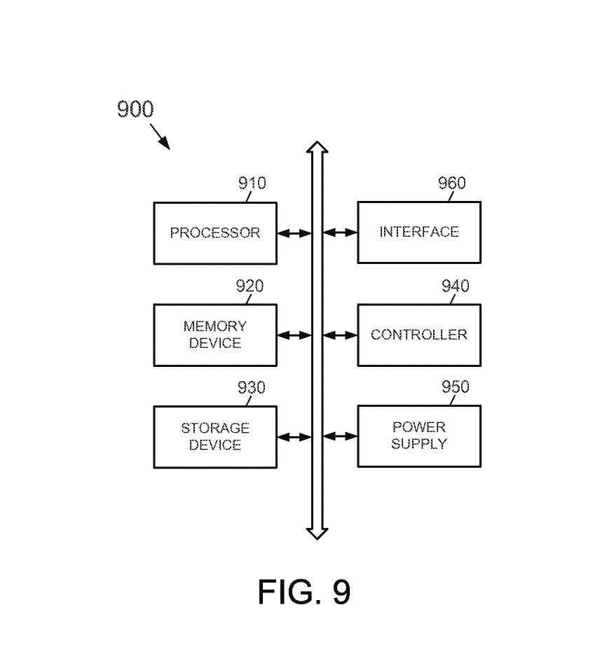

FIG. 9 depicts a block diagram illustrating an exemplary mobile device 900 that comprises one or more thermally enhanced POP structures disclosed herein. Referring to FIG. 9, a mobile device 900 may comprise a processor 910, a memory device 920, a storage device 930, a display device 940, a power supply 950 and an image sensor 960. The mobile device 900 may further comprise ports that communicate with a video card, a sound card, a memory card, a USB device, other electronic devices, etc.

The processor 910 may perform various calculations or tasks. According to exemplary embodiments, the processor 910 may be a microprocessor or a CPU. The processor 910 may communicate with the memory device 920, the storage device 930, and the display device 940 via an address bus, a control bus, and/or a data bus. In some exemplary embodiments, the processor 910 may be coupled to an extended bus, such as a peripheral component interconnection (PCI) bus or a PCI Express (PCIe) bus. The memory device 920 may store data for operating the mobile device 900. For example, the memory device 920 may be implemented with, but is not limited to, a dynamic random access memory (DRAM) device, a mobile DRAM device, a static random access memory (SRAM) device, a phase-change random access memory (PRAM) device, a ferroelectric random access memory (FRAM) device, a resistive random access memory (RRAM) device, and/or a magnetic random access memory (MRAM) device. The memory device 920 comprises a magnetic random access memory (MRAM) according to exemplary embodiments disclosed herein. The storage device 930 may comprise a solid-state drive (SSD), a hard disk drive (HDD), a CD-ROM, etc. The display device 940 may comprise a touch-screen display. The mobile device 900 may further include an input device (not shown), such as a touchscreen different from display device 940, a keyboard, a keypad, a mouse, etc., and an output device, such as a printer, a display device, etc. The power supply 950 supplies operation voltages for the mobile device 900.

The image sensor 960 may communicate with the processor 910 via the buses or other communication links. The image sensor 960 may be integrated with the processor 910 in one chip, or the image sensor 960 and the processor 910 may be implemented as separate chips.

At least a portion of the mobile device 900 may be packaged in various forms, such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi chip package (MCP), wafer-level fabricated package (WFP), or wafer-level processed stack package (WSP). The mobile device 900 may be a digital camera, a mobile phone, a smart phone, a portable multimedia player (PMP), a personal digital assistant (PDA), a computer, a tablet, etc.

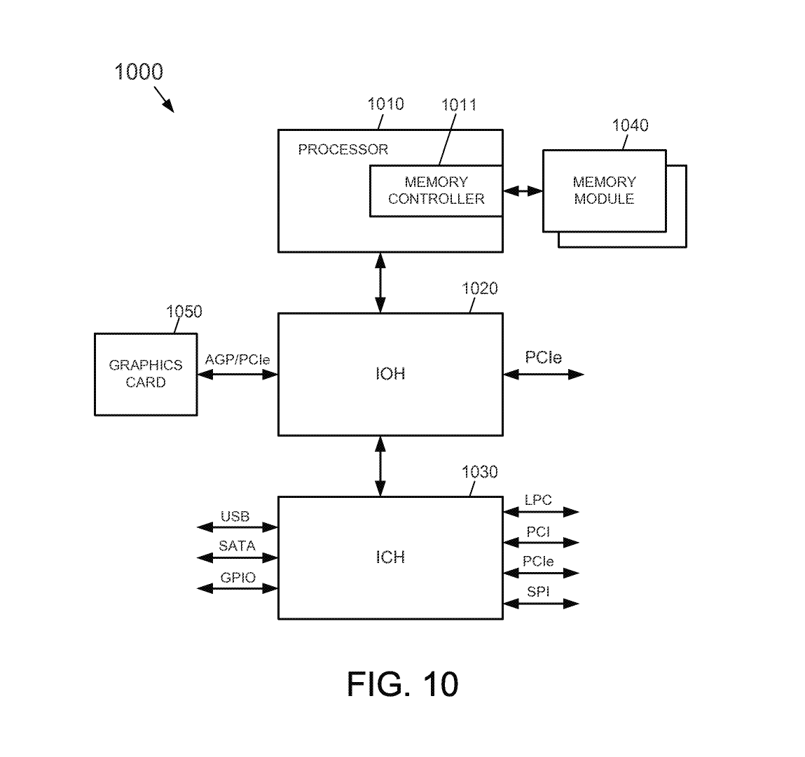

FIG. 10 depicts a block diagram illustrating an exemplary computing system 1000 that comprises one or more thermally enhanced POP structures disclosed herein. Referring to FIG. 10, a computing system 1000 comprises a processor 1010, an input/output hub (IOH) 1020, an input/output controller hub (ICH) 1030, at least one memory module 1040 and a graphics card 1050. In some exemplary embodiments, the computing system 1000 may comprise a server system, a personal computer (PC), a server computer, a workstation, a laptop computer, a mobile phone, a smart phone, a personal digital assistant (PDA), a portable multimedia player (PMP), a digital camera), a digital television, a set-top box, a music player, a portable game console, a navigation system, etc.

The processor 1010 may perform various computing functions, such as executing specific software for performing specific calculations or tasks. For example, the processor 1010 may comprise a microprocessor, a central process unit (CPU), a digital signal processor, or the like. In some embodiments, the processor 1010 may include a single core or multiple cores. For example, the processor 1010 may be a multi-core processor, such as a dual-core processor, a quad-core processor, a hexa-core processor, etc. In some embodiments, the computing system 1000 may comprise a plurality of processors. The processor 1010 may comprise an internal or external cache memory.

The processor 1010 may include a memory controller 1011 for controlling operations of the memory module 1040. The memory controller 1011 included in the processor 1010 may be referred to as an integrated memory controller (IMC). A memory interface between the memory controller 1011 and the memory module 1040 may be implemented with a single channel including a plurality of signal lines, or may be implemented with multiple channels, to each of which at least one memory module 1040 may be coupled. In some embodiments, the memory controller 1011 may be located inside the input/output hub 1020, which may be referred to as memory controller hub (MCH).

The input/output hub (IOH) 1020 may manage data transfer between processor 1010 and devices, such as the graphics card 1050. The input/output hub 1020 may be coupled to the processor 1010 via various interfaces. For example, the interface between the processor 1010 and the input/output hub 1020 may be a front side bus (FSB), a system bus, a HyperTransport, a lightning data transport (LDT), a QuickPath interconnect (QPI), a common system interface (CSI), etc. In some exemplary embodiments, the computing system 1000 may comprise a plurality of input/output hubs. The input/output hub 1020 may provide various interfaces with the devices. For example, the input/output hub 1020 may provide an accelerated graphics port (AGP) interface, a peripheral component interface-express (PCIe), a communications streaming architecture (CSA) interface, etc.

The graphics card 1050 may be coupled to the input/output hub 1020 via AGP or PCIe. The graphics card 1050 may control a display device (not shown) for displaying an image. The graphics card 1050 may include an internal processor for processing image data and an internal memory device. In some embodiments, the input/output hub 1020 may include an internal graphics device along with or instead of the graphics card 1050 outside the graphics card 1050. The graphics device included in the input/output hub 1020 may be referred to as integrated graphics. Further, the input/output hub 1020 including the internal memory controller and the internal graphics device may be referred to as a graphics and memory controller hub (GMCH).

The input/output controller hub (ICH) 1030 may perform data buffering and interface arbitration to efficiently operate various system interfaces. The input/output controller hub 1030 may be coupled to the input/output hub 1020 via an internal bus, such as a direct media interface (DMI), a hub interface, an enterprise Southbridge interface (ESI), PCIe, etc. The input/output controller hub 1030 may provide various interfaces with peripheral devices. For example, the input/output controller hub 1030 may provide a universal serial bus (USB) port, a serial advanced technology attachment (SATA) port, a general purpose input/output (GPIO), a low pin count (LPC) bus, a serial peripheral interface (SPI), PCI, PCIe, etc.

In some exemplary embodiments, the processor 1010, the input/output hub 1020 and the input/output controller hub 1030 may be implemented as separate chipsets or separate integrated circuits. In other exemplary embodiments, at least two of the processor 1010, the input/output hub 1020 and the input/output controller hub 1030 may be implemented as a single chipset.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the subject matter disclosed herein. Accordingly, all such modifications are intended to be included within the scope of the appended claims.

1. A package-on-package (POP) structure, comprising:
a top package comprising:
a package substrate comprising a first side and a second side;
a plurality of top-package semiconductor devices on the first side of the package substrate;
a molding material layer formed on and between the plurality of top-package semiconductor devices; and
a thermal path disposed between a first top-package semiconductor device and a second top-package semiconductor device, the thermal path extending through the package substrate from the second side of the package substrate to a top surface of the molding material layer.

2. The POP structure according to claim 1, further comprising a bottom package comprising at least one bottom-package semiconductor device, and
wherein the at least one thermal path is disposed over and is thermally coupled to the at least one bottom-package semiconductor device.

3. The POP structure according to claim 2, wherein the at least one thermal path is disposed substantially centered over the at one bottom-package semiconductor device.

4. The POP structure according to claim 2, wherein the at least one bottom-package semiconductor device comprises a backside metallization that is thermally coupled to the at least one thermal path.

5. The POP structure according to claim 2, wherein the top package further comprises:
a thermal interface material (TIM) layer formed on a top surface of the molding material layer; and
a heat slug formed on a top surface of the TIM layer.

6. The POP structure according to claim 2, wherein the at least one thermal path comprises at least one via extending through the top package from the second side of the package substrate to the top surface of the molding material layer, the at least one via being filled with a low thermal resistance material.

7. The POP structure according to claim 2, wherein the package substrate comprises at least one via extending through the package substrate and in alignment with the at least one thermal path, the at least one via extending through the package substrate being filled with a low thermal resistance material, and
wherein the at least one thermal path comprises at least one trench extending through the top package from the first side of the package substrate to the top surface of the molding material layer in alignment with the at least one via extending through the package substrate, the at least one trench being filled with a low thermal resistance material.

8. The POP structure according to claim 7, wherein the at least one trench is further filled with a heat slug and the low thermal resistance material.

9. A semiconductor package, comprising:
a bottom package comprising at least one bottom-package semiconductor device; and
a top package on the bottom package, the top package comprising a first side and a second side, a package substrate disposed at the first side of the top package, a plurality of top-package semiconductor devices disposed on the package substrate, and at least one thermal path disposed between a first top-package semiconductor device and a second top-package semiconductor device, the thermal path extending from the first side of the top package through the package substrate to the second side of the top package.

10. The semiconductor device according to claim 9, wherein the at least one thermal path is disposed over and is thermally coupled to the at least one bottom-package semiconductor device.

11. The semiconductor device according to claim 10, wherein the at least one thermal path is disposed substantially centered over the at one bottom-package semiconductor device.

12. The semiconductor device according to claim 10, wherein the at least one bottom-package semiconductor device comprises a backside metallization that is thermally coupled to the at least one thermal path.

13. The semiconductor device according to claim 10, wherein the top package further comprises a molding material layer formed on and between the plurality of top-package semiconductor devices, and
wherein the at least one thermal path extends through the molding material layer between the first top-package semiconductor device and the second top-package semiconductor device from the first side to the second side of the top package.

14. The semiconductor device according to claim 13, wherein the top package further comprises:
a thermal interface material (TIM) layer formed on a top surface of the molding material layer; and
a heat slug formed on a top surface of the TIM layer.

15. The semiconductor device according to claim 13, wherein the at least one thermal path comprises at least one via extending through the top package from the first side to the top surface of the molding material layer, the at least one via being filled with a low thermal resistance material.

16. The semiconductor device according to claim 13, wherein the package substrate of the bottom package comprises at least one via extending through the package substrate and in alignment with the at least one thermal path, the at least one via extending through the package substrate being filled with a low thermal resistance material, and
wherein the at least one thermal path comprises at least one trench extending through the top package from the first side of the package substrate to the top surface of the molding material layer in alignment with the at least one via extending through the package substrate, the at least one trench being filled with a low thermal resistance material.

17. The semiconductor device according to claim 16, wherein the at least one trench is further filled with a heat slug and the low thermal resistance material.

18. A semiconductor package, comprising:
a bottom package comprising:
a bottom-package substrate comprising a first side and a second side; and
at least one controller-type semiconductor device on the first side of the bottom-package substrate, the at least one controller-type semiconductor device comprising a first side, a second side and a backside metallization on the first side of the controller-type semiconductor device; and
a top package on the bottom package, the top package comprising:
a first side and a second side;
a package substrate disposed at the first side of the top package;
a plurality of top-package semiconductor devices on the package substrate, at least one top-package semiconductor device comprising a memory semiconductor device;
a molding material layer formed on and between the plurality of top-package semiconductor devices;
a thermal interface material (TIM) layer formed on a top surface of the molding material layer; and
a heat slug formed on a top surface of the TIM layer and being thermally coupled to the TIM layer; and
at least one thermal path disposed between a first top-package semiconductor device and a second top-package semiconductor device, the thermal path extending from the first side of the top package through the package substrate to the TIM layer, and the thermal path being disposed over and being thermally coupled to the at least one bottom-package semiconductor device.

19. The semiconductor device according to claim 18, wherein the at least one thermal path comprises at least one via extending through the top package from the first side to the top surface of the molding material layer, the at least one via being filled with a low thermal resistance material.

20. The semiconductor device according to claim 18, wherein the package substrate of the bottom package comprises at least one via extending through the package substrate and in alignment with the at least one thermal path, the at least one via extending through the package substrate being filled with a low thermal resistance material, and
wherein the at least one thermal path comprises at least one trench extending through the top package from the first side of the package substrate to the top surface of the molding material layer in alignment with the at least one via extending through the package substrate, the at least one trench being filled with a low thermal resistance material.
